(19) United States
(12) Patent Application Publication
(10) Pub. No.: US 2023/0318326 A1
(43) Pub. Date: Oct. 5, 2023

(54) CHARGING PLUG WITH FAST/SLOW CHARGING SWITCHING FUNCTION AND CHARGING APPARATUS

(71) Applicant: TacSense Technology (Shenzhen) Co., Ltd., Shenzhen (CN)

(72) Inventors: Hui Yang, Shenzhen (CN); Kun Yang, Shenzhen (CN); Fenghong Fu, Shenzhen (CN)

(73) Assignee: TacSense Technology (Shenzhen) Co., Ltd., Shenzhen (CN)

(21) Appl. No.: 17/743,487

(22) Filed: May 13, 2022

(30) Foreign Application Priority Data
Mar. 31, 2022 (CN) 202220727596.5

(51) Int. Cl. H02J 7/00; H01R 31/06

(52) U.S. Cl. CPC H02J 7/0042; H02J 7/0047; H01R 31/065; H05K 7/1427

(57) ABSTRACT

A charging plug with a fast/slow charging switching function includes a housing, a control switch, a control module, a charging module, a plug connector and a charging interface. The control module and the charging module are accommodated in the housing, the control switch and the charging module are electrically connected to the control module separately, the plug connector and the charging interface are electrically connected to the charging module separately, the control switch generates a trigger signal in response to a user operation and sends the trigger signal to the control module, and the control module controls, based on the trigger signal, the charging module to switch between a fast charging mode and a slow charging mode. A charging apparatus with the above charging plug is further provided. Users can freely select a charging mode according to their own needs.

### CROSS REFERENCE TO THE RELATED APPLICATIONS

This application is based upon and claims priority to Chinese Patent Application No. 202220727596.5, filed on Mar. 31, 2022, the entire contents of which are incorporated herein by reference.

### TECHNICAL FIELD

The present invention relates to the technical field of charging plugs, and in particular, to a charging plug with a fast/slow charging switching function and a charging apparatus.

### BACKGROUND

Currently, most of the charging plugs on the market have a fast charging function to fully charge the electronic device in a short period of time. In actual use, combination of fast charging and slow charging can help improve the charging efficiency of the electronic device and extend the service life of the battery. In this context, charging plugs that can switch between fast and slow charging are emerging in the market.

The prior charging plug enabling fast/slow charging switching is usually provided with a power switch, to automatically control the fast/slow charging function of the charging plug. During use of such charging plug, users cannot switch between fast and slow charging according to their own will, which greatly affects the user experience.

### SUMMARY

In order to resolve the technical problem that the charging plug cannot switch between fast and slow charging according to actual needs, the present invention provides a charging plug with a fast/slow charging switching function, and further discloses a charging apparatus with the charging plug.

The present invention uses the following technical solutions:

Solution 1: A charging plug with a fast/slow charging switching function is disclosed, including a housing, a control switch, a control module, a charging module, a plug connector and a charging interface, where the control module and the charging module are accommodated in the housing, the control switch and the charging module are electrically connected to the control module separately, the plug connector and the charging interface are electrically connected to the charging module separately, the control switch generates a trigger signal in response to a user operation and sends the trigger signal to the control module, and the control module controls, based on the trigger signal, the charging module to switch between a fast charging mode and a slow charging mode.

Optionally, the housing includes a housing body and a housing cover, the housing body is provided with a mounting slot for mounting the control switch, and the housing cover is removably connected to the housing body and is disposed on a side close to the mounting slot to seal the mounting slot.

Optionally, the control switch includes an elastic member, a pressure sensor and a circuit board, the circuit board abuts against the mounting slot, the pressure sensor is clamped between the elastic member and the circuit board, the pressure sensor is electrically connected to the circuit board, and the circuit board is electrically connected to the control module.

Optionally, the control switch is completely accommodated in a space defined by the mounting slot and the housing cover, the elastic member abuts against the housing cover, the housing cover is provided with a pressing area on a side away from the elastic member, and the pressing area corresponds to a position of the pressure sensor.

Optionally, the control switch is partially accommodated in a space defined by the mounting slot and the housing cover, the control switch further includes a switch housing, the elastic member is disposed in and abuts against the switch housing, the housing cover is provided with a through hole matching the switch housing, and the switch housing passes through the through hole and protrudes from the housing cover.

Optionally, the circuit board is a rigid printed circuit board (PCB), the PCB is disposed in the mounting slot, and the control module is disposed on a side close to the mounting slot.

Optionally, the circuit board is a flexible printed circuit (FPC), the housing body further includes an accommodating cavity in communication with the mounting slot, the control module and the charging module are disposed in the accommodating cavity, and the FPC is disposed in the mounting slot through a reinforcing plate and extends into the accommodating cavity to be electrically connected to the control module.

Optionally, the charging module includes a fast charging module and a slow charging module, and the control module controls, based on the trigger signal, the fast charging module or the slow charging module to operate, to switch between the fast charging mode and the slow charging mode.

Optionally, the charging plug further includes an identification apparatus electrically connected to the control module, and the identification apparatus is configured to differentially display whether the charging module is operating in the fast charging mode or the slow charging mode.

Optionally, the plug connector and the charging interface are disposed on opposite sides of the housing, and the control switch and the charging interface are disposed on a same side of the housing.

Solution 2: A charging apparatus is disclosed, including the charging plug with a fast/slow charging switching function according to Solution 1 or any of the optional solutions and a power cable adapted to the charging plug, where the power cable is electrically connected to the charging plug through the charging interface.

According to the above solutions of the present invention, users can freely select a charging mode according to their own needs, which greatly improves the user experience.

### BRIEF DESCRIPTION OF THE DRAWINGS

FIG. 1 is a schematic diagram of an overall structure of a charging plug according to an embodiment;

FIG. 2A and FIG. 2B are separately a schematic structural diagram and a partial enlarged view of an embodiment of a control switch;

FIG. 3A and FIG. 3B are separately a schematic structural diagram and a partial enlarged view of another embodiment of a control switch; and

FIG. 4A and FIG. 4B are separately a schematic diagram and a partial enlarged view of an internal structure of a charging plug according to an embodiment.

Reference numerals: 100-housing, 101-housing body, 102-housing cover, 103-mounting slot, 104-through hole, 200-control switch, 201-switch housing, 202-elastic member, 203-pressure sensor, 204-circuit board, 2041-FPC, 2042-reinforcing plate, 300-control module, 400-USB interface, 500-plug connector, and 600-light-emitting diode (LED) lamp.

### DETAILED DESCRIPTION OF THE EMBODIMENTS

The technical solutions of this application are clearly and completely described below with reference to the specific embodiments and the accompanying drawings.

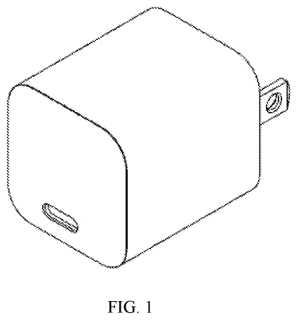

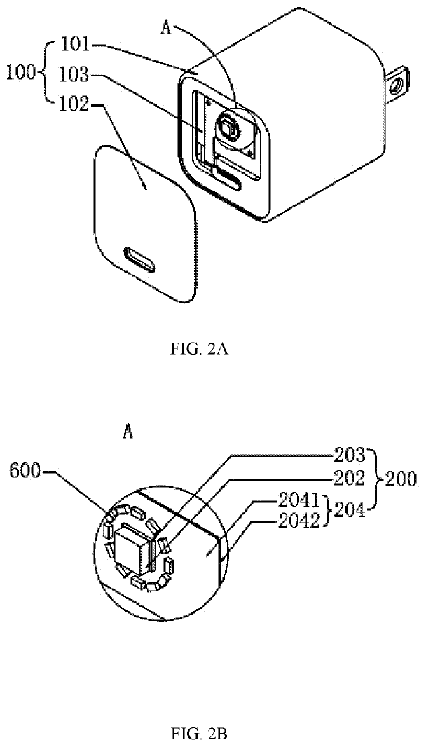

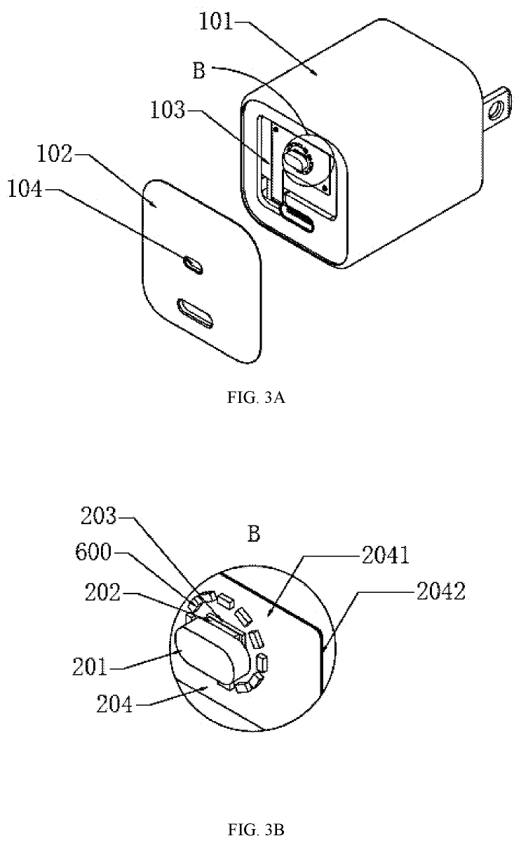

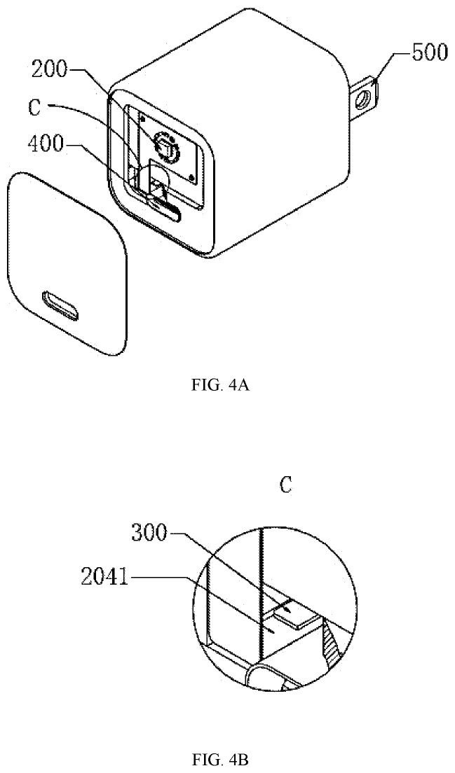

Referring to FIG. 1, FIG. 2A, FIG. 2B, FIG. 3A, FIG. 3B, FIG. 4A, and FIG. 4B, an embodiment provides a charging plug with a fast/slow charging switching function. The charging plug mainly includes a housing 100, a control switch 200, a control module 300 and a charging module. The control module 300 and the charging module are accommodated in the housing 100, the control switch 200 is completely or partially accommodated in the housing 100, and the control module 300 is electrically connected to the control switch 200 and the charging module separately. The charging module may include a fast charging module and a slow charging module. During use, a user directly or indirectly presses the control switch 200, the control switch 200 generates a trigger signal in response to the pressing operation and sends the trigger signal to the control module 300. The control module 300 controls, based on the trigger signal, the charging module to switch from the fast charging module to the slow charging module or switch from the slow charging module to the fast charging module, such that the charging plug switches between fast charging and slow charging.

The housing 100 includes a housing body 101 and a housing cover 102, and the housing body is provided with an accommodating cavity for accommodating the control module 300 and the charging module. One end of the housing body 101 is further provided with a mounting slot 103 for mounting the control switch 200, and the mounting slot 103 is in communication with the accommodating cavity. The housing cover 102 is removably connected to the housing body 101 and is disposed on a side close to the mounting slot 103 to seal the mounting slot 103. The removable connection between the housing cover 103 and the housing body 101 facilitates installation and maintenance of the control switch 200. Further, the control module 300 may be disposed in the accommodating cavity of the housing body through a piece of control motherboard.

As shown in FIG. 2A and FIG. 2B, in an embodiment, the control switch 200 is completely accommodated in a space defined by the mounting slot 103 and the housing cover 102. Specifically, the control switch 200 includes an elastic member 202, a pressure sensor 203 and a circuit board 204. The elastic member 203 abuts against the housing cover 102, the circuit board 204 abuts against the mounting slot 103, and the pressure sensor 203 is clamped between the elastic member 202 and the circuit board 204. The pressure sensor 203 is electrically connected to the circuit board 204, and the circuit board 204 is electrically connected to the control module 300. During use, the user presses the housing cover 102, the housing cover 102 transmits the pressure to the pressure sensor 203 through the elastic member 202, the pressure sensor 203 transmits pressure information to the circuit board 204, and the circuit board 204 transmits the pressure information to the control module 300. The control module 300 controls the switch between the fast charging module and the slow charging module based on the pressure information. In this design, the control switch 200 is completely accommodated in the space defined by the mounting slot 103 and the housing cover 102. In this way, the housing cover 102 can protect the control switch 200, thereby further extending the service life of the control switch 200. In addition, since the control switch 200 is completely accommodated in the space defined by the mounting slot 103 and the housing cover 102, the overall appearance of the charging plug is simpler and more beautiful. In this embodiment, the outside of the housing cover 102, that is, a side of the housing cover 102 away from the elastic member 202, may be provided with an obvious pressing area for user identification, and the pressing area corresponds to a position of the pressure sensor 203. The pressing area may be a button logo, a groove or a protrusion disposed on the housing body 101.

As shown in FIG. 3A and FIG. 3B, in another embodiment, the control switch 200 is partially accommodated in the space defined by the mounting slot 103 and the housing cover 102 and partially protrudes from the housing cover 102. Specifically, the control switch 200 includes a switch housing 201, an elastic member 202, a pressure sensor 203 and a circuit board 204. The elastic member 202 is disposed in and abuts against the switch housing 201, the circuit board 204 abuts against the mounting slot 103, and the pressure sensor 203 is clamped between the elastic member 203 and the circuit board 204. The housing cover 102 is further provided with a through hole 104 matching the switch housing 201, and the switch housing 201 passes through the through hole 104 and protrudes from the housing cover 102. The pressure sensor 203 is electrically connected to the circuit board 204, and the circuit board 204 is electrically connected to the control module 200. During use, the user presses the switch housing 201, the switch housing 201 transmits the pressure to the pressure sensor 203 through the elastic member 202, the pressure sensor 203 transmits the pressure information to the circuit board 204, and the circuit board 204 transmits the pressure information to the control module 300. The control module 300 controls the switch between the fast charging module and the slow charging module based on the pressure information.

The pressure sensor 203 is configured to detect changes in a pressure parameter when pressed. The circuit board 204 converts the changed pressure parameter into an electrical parameter, and transmits the electrical parameter to the control module 300. The control module 300 determines, based on the magnitude of the electrical parameter, whether to switch between the fast charging module and the slow charging module. Specifically, when the press pressure exceeds a predetermined threshold, the charging mode is controlled to switch, for example, switch from the fast charging mode to the slow charging mode, or switch from the slow charging mode to the fast charging mode.

The elastic member 202 is a material with a certain degree of elasticity, preferably silicone.

The circuit board 204 may be a rigid PCB, or a flexible FPC with a reinforcing plate.

If the circuit board 204 is the rigid PCB, the circuit board 204 is positioned directly in the mounting slot 103. The control module 300 is disposed on a side close to the mounting slot 103, facilitating electrical connection between the circuit board 204 and the control module 300. The circuit board 204 may be positioned in the mounting slot 103 through bonding, bolting, bayonet connection, positioning post connection or the like.

If the circuit board 204 is the flexible FPC 2041 with the reinforcing plate, the FPC 2041 is disposed on the reinforcing plate 2042 and is electrically connected to the pressure sensor 203, and the reinforcing plate 2042 is positioned in the mounting slot and supports the FPC 2041. The control module 300 may be disposed on a side close to the mounting slot 103 or may be disposed in the accommodating cavity. In this design, the control module 300 is disposed in the accommodating cavity. Since the charging module is disposed in the accommodating cavity, disposing the control module in the accommodating cavity facilitates the electrical connection between the control module 300 and the charging module, such that the overall structure is more compact. Since the FPC 2041 is flexible, the FPC 2041 can smoothly extends from the mounting slot 103 into the accommodating cavity to be electrically connected to the control module 300. The reinforcing plate 2042 may be positioned in the mounting slot 103 through bonding, bolting, bayonet connection, positioning post connection or the like, and the FPC 2041 may be disposed on the reinforcing plate 2042 through bonding. The reinforcing plate 2042 is a material with a certain strength, preferably stainless steel.

The fast charging module is disposed to meet the fast charging protocol of the applied terminal, for example, Huawei Fast Charge Protocol (FCP) and Super Charge Protocol (SCP), and Apple USB Power Delivery (PD) Specification. The slow charging module mainly refers to a charging mode that does not meet the fast charging protocol, that is, a regular charging mode. The fast charging module or the slow charging module may be of a conventional fast charging or slow charging circuit design, as long as the corresponding fast charging or slow charging function can be achieved. This is not limited herein. Certainly, in another embodiment, the functions of the fast charging module and the slow charging module may alternatively be implemented through one module combined with software, to switch between the two charging modes.

Further, in order to facilitate user identification, the charging plug is further provided with an identification apparatus. The identification apparatus and the control switch are disposed on a same side, and the identification apparatus is electrically connected to the control module. The identification apparatus has a fast charging display mode and a slow charging display mode, and the fast charging display mode and the slow charging display mode correspond to the fast charging module and the slow charging module respectively. To be specific, when the charging plug is in the fast charging mode, the identification apparatus emits an identification mark through the fast charging display mode, to remind the user of the fast charging module; or when the charging plug is in the slow charging mode, the identification apparatus emits an identification mark through the slow charging display mode, to remind the user of the slow charging module. In an embodiment, the identification apparatus include two groups of LED lamps 600 electrically connected to the control module separately. The two groups of LED lamps 600 have different colors. One group of LED lamps 600 corresponds to the fast charging display mode, and the other group of LED lamps 600 corresponds to the slow charging display mode. In another embodiment, the identification apparatus is a group of LED lamps 600 electrically connected to the control module, the LED lamps 600 have two color states, and different color states correspond to different display modes.

As shown in FIG. 4A and FIG. 4B, the charging plug further includes a charging interface 400 and a plug connector 500, the charging interface 400 is electrically connected to the charging module, the plug connector 500 is also electrically connected to the charging module, and the charging interface 400 and the plug connector 500 are disposed on two opposite sides of the housing 100. In this design, the control switch 200 and the charging interface 400 are disposed on a same side. In this way, when the user uses the charging plug, the control switch 200 can face the user, facilitating the user operation. Certainly, the control switch 200 may alternatively be disposed in another position, as long as it is easy for the user to press. The charging interface 400 may be a USB interface.

The present invention further provides a charging apparatus, including the charging plug with a fast/slow charging switching function according to the above embodiments and a power cable adapted to the charging plug. A connector is disposed at each end of the power cable, for example, a Type-C connector at one end and a USB connector at the other end. The USB connector is electrically connected to a USB interface of the charging plug.

It should be noted that although the solutions of the present invention are described above with reference to the accompanying drawings, the present invention is not limited to the aforementioned specific embodiments and application fields, and the above specific embodiments are merely illustrative, instructive, rather than restrictive. Those of ordinary skills in the art can make various forms under the inspiration of this specification and without departing from the claimed scope of the claims of the present invention, and these forms are all within the claimed scope of the present invention.

What is claimed is:

1. A charging plug with a fast/slow charging switching function, comprising a housing, a control switch, a control module, a charging module, a plug connector and a charging interface, wherein
the control module and the charging module are accommodated in the housing,
the control switch and the charging module are electrically connected to the control module separately,
the plug connector and the charging interface are electrically connected to the charging module separately,
the control switch generates a trigger signal in response to a user operation and the control switch sends the trigger signal to the control module, and
the control module controls, based on the trigger signal, the charging module to switch between a fast charging mode and a slow charging mode.

2. The charging plug according to claim 1, wherein
the housing comprises a housing body and a housing cover,
the housing body is provided with a mounting slot for mounting the control switch,
the housing cover is removably connected to the housing body, and
the housing cover is disposed on a side adjacent to the mounting slot to seal the mounting slot.

3. The charging plug according to claim 2, wherein
the control switch comprises an elastic member, a pressure sensor and a circuit board,
the circuit board abuts against the mounting slot,
the pressure sensor is clamped between the elastic member and the circuit board,
the pressure sensor is electrically connected to the circuit board, and
the circuit board is electrically connected to the control module.

4. The charging plug according to claim 3, wherein
the control switch is completely accommodated in a space defined by the mounting slot and the housing cover,
the elastic member abuts against the housing cover,
the housing cover is provided with a pressing area on a side away from the elastic member, and
the pressing area corresponds to a position of the pressure sensor.

5. The charging plug according to claim 3, wherein
the control switch is partially accommodated in a space defined by the mounting slot and the housing cover,
the control switch further comprises a switch housing,
the elastic member is disposed in the switch housing and the elastic member abuts against the switch housing,
the housing cover is provided with a through hole matching the switch housing,
the switch housing passes through the through hole, and
the switch housing protrudes from the housing cover.

6. The charging plug according to claim 3, wherein the circuit board is a rigid printed circuit board (PCB), the rigid PCB is disposed in the mounting slot, and the control module is disposed on the side adjacent to the mounting slot.

7. The charging plug according to claim 3, wherein
the circuit board is a flexible printed circuit (FPC),
the housing body further comprises an accommodating cavity in communication with the mounting slot,
the control module and the charging module are disposed in the accommodating cavity,
the FPC is disposed in the mounting slot through a reinforcing plate, and
the FPC extends into the accommodating cavity to be electrically connected to the control module.

8. The charging plug according to claim 1, wherein the charging module comprises a fast charging module and a slow charging module, and the control module controls, based on the trigger signal, the fast charging module or the slow charging module to operate, to switch between the fast charging mode and the slow charging mode.

9. The charging plug according to claim 1, further comprising an identification apparatus electrically connected to the control module, wherein the identification apparatus is configured to differentially display whether the charging module is operating in the fast charging mode or the slow charging mode.

10. The charging plug according to claim 1, wherein the plug connector and the charging interface are disposed on opposite sides of the housing, respectively, and the control switch and the charging interface are disposed on a same side of the housing.

11. A charging apparatus, comprising the charging plug according to claim 1 and a power cable, the power cable is adapted to the charging plug, wherein the power cable is electrically connected to the charging plug through the charging interface.

12. The charging plug according to claim 2, wherein the charging module comprises a fast charging module and a slow charging module, and the control module controls, based on the trigger signal, the fast charging module or the slow charging module to operate, to switch between the fast charging mode and the slow charging mode.

13. The charging plug according to claim 3, wherein the charging module comprises a fast charging module and a slow charging module, and the control module controls, based on the trigger signal, the fast charging module or the slow charging module to operate, to switch between the fast charging mode and the slow charging mode.

14. The charging plug according to claim 4, wherein the charging module comprises a fast charging module and a slow charging module, and the control module controls, based on the trigger signal, the fast charging module or the slow charging module to operate, to switch between the fast charging mode and the slow charging mode.

15. The charging plug according to claim 5, wherein the charging module comprises a fast charging module and a slow charging module, and the control module controls, based on the trigger signal, the fast charging module or the slow charging module to operate, to switch between the fast charging mode and the slow charging mode.

16. The charging plug according to claim 6, wherein the charging module comprises a fast charging module and a slow charging module, and the control module controls, based on the trigger signal, the fast charging module or the slow charging module to operate, to switch between the fast charging mode and the slow charging mode.

17. The charging plug according to claim 7, wherein the charging module comprises a fast charging module and a slow charging module, and the control module controls, based on the trigger signal, the fast charging module or the slow charging module to operate, to switch between the fast charging mode and the slow charging mode.

18. The charging plug according to claim 2, further comprising an identification apparatus electrically connected to the control module, wherein the identification apparatus is configured to differentially display whether the charging module is operating in the fast charging mode or the slow charging mode.

19. The charging plug according to claim 3, further comprising an identification apparatus electrically connected to the control module, wherein the identification apparatus is configured to differentially display whether the charging module is operating in the fast charging mode or the slow charging mode.

20. The charging plug according to claim 4, further comprising an identification apparatus electrically connected to the control module, wherein the identification apparatus is configured to differentially display whether the charging module is operating in the fast charging mode or the slow charging mode.
